(19) United States
(12) Patent Application Publication
(10) Pub. No.: US 2026/0244074 A1
(43) Pub. Date: Aug. 20, 2026

(54) OPTICAL COMPUTING DEVICE

(71) Applicant: National Chung Cheng University, Chiayi County (TW)

(72) Inventor: Zhi-Ting Ye, Miaoli County (TW)

(21) Appl. No.: 19/228,796

(22) Filed: Jun. 5, 2025

(30) Foreign Application Priority Data
Feb. 18, 2025 (TW) 114105920

(51) Int. Cl. G02F 1/365; H10F 55/25

(52) U.S. Cl. CPC G02F 1/365; H10F 55/25; G02F 2201/02

(57) ABSTRACT

The present application provides an optical computing device, which includes a light-emitting element, a lens element, an optical component and a light receiver. The lens element covers the light-emitting element. The lens element receives and collimates a light emitted by the light-emitting element. The optical component disposed on a side of the lens element. The optical component includes a light guide element, receiving the light on a side thereof, and emitting the light from another side thereof, a channel layer covering an outside of the light guide element, and an outer cladding layer covering an outside of the channel layer. The light receiver receives the light from the optical component, uses the channel layer to reduce the consumption of light inside the light guide element, and improves the light guide efficiency of the light guide element.

### FIELD OF THE INVENTION

The present application relates to an optical computing device, and more particularly to an optical computing device with high light guiding efficiency.

### BACKGROUND OF THE INVENTION

Photonic computers, also known as optical computers, are an advanced computer technology that uses photons as the computing unit, and main purpose of the photonic computers is to replace electrons in traditional electronic computers as the medium for information processing and transmission. The photonic computers are considered to have the potential of changing the architecture and performance of computers based on the characteristics of photons, such as high-speed transmission, low energy consumption, and high-capacity data processing capabilities. In existing arts, the development of photonic computers has mainly focused on researching how to use optical components to replace existing electronic components, especially in achieving optoelectronic hybrid systems without completely changing the existing computer architecture. This technical route is considered the best way to realize commercial optical computing at this stage.

In modern electronic computers, transistors serve as the basic components for logical operations and data processing, providing efficient binary data processing capabilities for computer systems. To replace transistors for photonic computers, existing arts have provided a concept of optical transistors. The optical transistors are realized through the use of materials with nonlinear refractive indices, including optical fibers and other nonlinear optical media. The materials have the ability to change the light intensity transmission characteristics, where the intensity of the incident light may influence the intensity of the light signal passing through the materials, similar to the gain response of current in bipolar transistors. Based on this characteristic, the optical transistors may be used to build optical logic gates, and the optical logic gates may be further assembled into core components such as central processing units (CPUs) of computers.

In the development of photonic computers, nonlinear optical materials are widely used to manipulate lights and achieve control of other lights. The nonlinear optical materials have high refractive index response characteristics, allowing precise adjustment of optical signals by changing the intensity of incident light. Based on this characteristic, nonlinear optical materials are used to manufacture optical logic gates, which are further integrated into advanced computing units. This design based on optical logic gates provides photonic computers with the ability to process binary data and lays the foundation for realizing optical operations.

Additionally, most research projects in the existing arts focus on the development of optoelectronic hybrid systems. The design concept of optoelectronic hybrid systems is to replace some electronic components in existing computers, such as logic gates, memory units, or data transmission modules, with optical components. This design of the optoelectronic hybrid systems allows optical and electronic components to work together, combining the advantages of photonic high-speed transmission and electronic computing stability. The optoelectronic hybrid systems are considered a short-term solution for the commercialization of photonic computers, as the optoelectronic hybrid systems do not require a complete and revolutionary transformation of existing computer architectures. Instead, improving system performance by gradually replacing electronic components.

In the optoelectronic hybrid systems, the design of the optical components needs to consider compatibility with electronic components, especially in terms of match for signal transmission mechanisms. Due to the differences in physical properties between optical and electronic signals, the existing art employs signal conversion modules to achieve mutual conversion between optical and electronic signals. Although the introduction of the conversion modules may solve the signal matching problem, it also increases the complexity of system design. At the same time, the operation of the signal conversion modules generates energy loss, which affects the overall efficiency of the optoelectronic hybrid systems. Therefore, how to achieve efficient conversion between optical and electronic signals in optoelectronic hybrid systems remains one of the challenges that the existing art needs to address.

Besides the research development of opto-electronic hybrid systems, the existing art also proposes the concept of an all-optical computer, which completely replaces all electronic components with optical components. However, this concept currently still faces various technical bottlenecks. For example, the design of optical transistors has not yet been able to reach the performance standards of the electronic transistors, especially in terms of response speed and stability. The performance of nonlinear optical materials also limits the application of all-optical logic gates, because the nonlinear optical materials usually require high-intensity optical signals to trigger nonlinear responses, which leads to a significant increase in energy demand during optical computation. This also includes the problem of poor light conductivity of light guides, which causes optical loss in the transmission path during optical computation, resulting in errors in detection signals or transmission signals. Accordingly, light guiding technology becomes more important, and therefore the industry needs a design that may improve the light guiding efficiency of optical computing devices.

In view of the problems of the existing art, the present application provides an optical computing device that utilizes an optical component with a channel layer to reduce the consumption of light inside the light guide element included in the optical component, thereby improving the light guiding efficiency of the light guide element.

### SUMMARY OF THE INVENTION

An objective of the present application is to provide an optical computing device, including an optical component, a collimating element, and a lens element. The optical component includes an outer cladding layer and a light guide element, and a channel layer is disposed between the cladding layer and the light guide element. The channel layer reduces the consumption of light inside the light guide element, thereby improving the light guiding efficiency of the light guide element.

To achieve the various objectives and effects mentioned above, the present application provides an optical computing device, comprising a light emitting element, a lens element, an optical component and a light receiver, the light emitting element emits a light, the lens element covers the light emitting element, the lens element receives and collimates the light, the optical component is disposed on a side of the lens element, the optical component comprises a light guide element, a side of the light guide element receives the light, and the light is emitted from another side of the light guide element, the light guide element comprises a inner cladding layer, a channel layer covering an outer side of the inner cladding layer of the light guide element, an outer cladding layer covering an outer side of the channel layer, the light receiver is disposed on another side of the light guide element, the light receiver receives the light and converts it into a second signal, the second signal is equal to the first signal; By this structure, an optical computing device capable of improving light guide efficiency is provided.

In an embodiment of the present application, wherein the light emitting element is at least one light emitting diode.

In an embodiment of the present application, wherein the lens element is a total reflection collimating lens.

In an embodiment of the present application, the optical computing device further comprising a light condensing element, disposed on a side of the lens element and receiving the emitted light.

In an embodiment of the present application, wherein the light guide element is an optical fiber.

In an embodiment of the present application, wherein the channel layer is filled with air or an inert gas.

In an embodiment of the present application, wherein the channel layer is filled with a reflective material.

In an embodiment of the present application, wherein a refractive index of the reflective material is greater than a refractive index of the light guide element.

In an embodiment of the present application, wherein the covering layer is opaque.

In an embodiment of the present application, wherein the light source is a matrix light source, and the light receiver is a matrix light receiver.

### BRIEF DESCRIPTION OF DRAWINGS

FIG. 1A and FIG. 1B are schematic diagrams according to a first embodiment of the present application;

FIG. 2A and FIG. 2B are schematic diagrams according to a second embodiment of the present application;

FIGS. 3A-3B are schematic diagrams of a light condensing element according to an embodiment of the present disclosure;

FIG. 4 is a schematic diagram of a mirror structure according to an embodiment of the present disclosure; and

FIGS. 5A-5B are schematic diagrams of a lens element according to an embodiment of the present disclosure.

### DETAILED DESCRIPTION

To overcome the shortcomings of the existing art, the present disclosure provides an optical computing device, which comprises a light emitting element, a lens element, an optical component and a light receiver, wherein the optical component comprises an outer cladding layer covering an outer side of a light guide element, and a channel layer is arranged between the cladding layer and the light guide element, and the difference in refractive index between the channel layer and the light guide element allows the light inside the light guide element to be totally reflected, thereby reducing the consumption of light, improving the light guide efficiency of the light guide element to overcome the problem of poor light guide efficiency of the existing art.

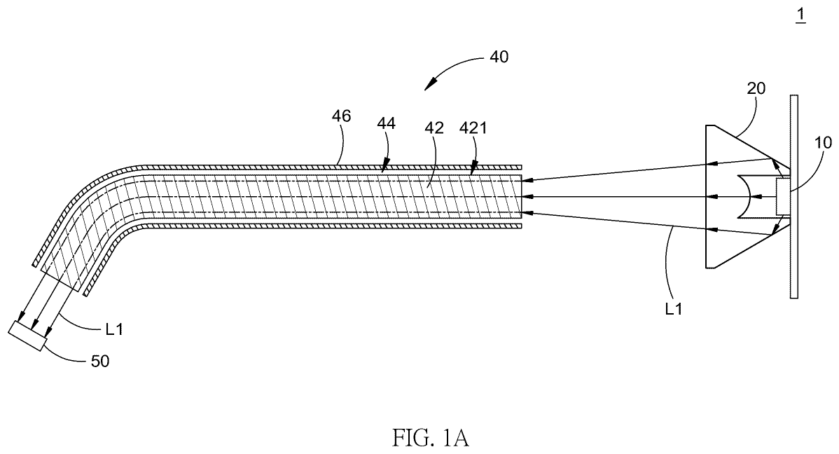

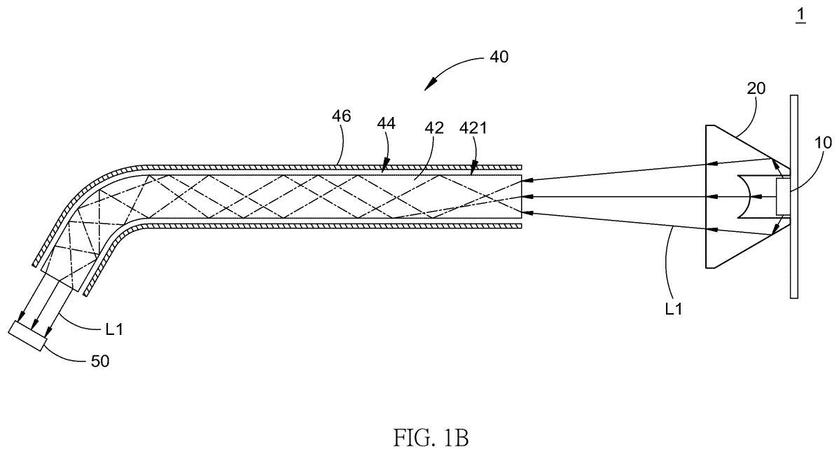

Referring to FIGS. 1A-1B, which are schematic diagrams of according to a first embodiment of the present disclosure, as shown in figures, the present embodiment is a first embodiment, and the present embodiment is to provide an optical computing device 1, which receives a first signal and converts the first signal into a light L1, and the optical computing device 1 comprises a light emitting element 10, a lens element 20, an optical component 40 and a light receiver 50.

Referring to FIG. 1A and FIG. 1B again, as shown in the figures, in this embodiment, the light emitting element 10 emits the light L1, a side of the lens element 20 covers the light emitting element 10, further, a groove is set on the side of the lens element 20 for covering the light emitting element 10, the lens element 20 receives and collimates the light L1, and makes the light L1 directly illuminate to the optical component 40, the optical component 40 is set on a side (image side) of the lens element 20, the optical component 40 includes a light guide element 42, a channel layer 44 and an outer cladding layer 46, a side of the light guide element 42 receives the light L1, and the light L1 is emitted from another side of the light guide element 42, the light guide element 42 includes an inner cladding layer 421, the channel layer 44 covers an outside of the inner cladding layer 421 of the light guide element 42, the outer cladding layer 46 covers an outside of the channel layer 44, the light receiver 50 is set on another side of the light guide element 42, the light receiver 50 receives the light L1, and converts the light L1 into a second signal, the second signal is equal to the first signal, so as to complete the signal transmission.

Continued with mentioned above, the outer cladding layer 46 is opaque, the outer cladding layer 46 covers the outside of the light guide element 42, and the channel layer 44 is correspondingly set between the light guide element 42 and the outer cladding layer 46.

Continued with mentioned above, in this embodiment, the first signal and the second signal are digital signals.

Continued with mentioned above, in this embodiment, the channel layer 44 is filled with air or inert gas, when the light L1 is conducted in the inside of the light guide element 42, part of the light L1 is totally reflected on the inner wall of the light guide element 42, for example, the inner cladding layer 421, the channel layer 44 may avoid the outer cladding layer 46 absorbing the light L1, so as to make the light guide rate of the light guide element 42 not to be reduced.

In an embodiment, the light source 10 is at least one light emitting diode (LED), the light source 10 may also be a light emitting array, the light L1 emitted by the light source 10 includes infrared light, ultraviolet light or blue light, when the present application is applied to optical computing device, the light L1 is infrared light preferably; the present application may also be applied to dental light curing device, when the present application is applied to light curing device, the light L1 is ultraviolet light or blue light preferably.

In an embodiment, the lens element 20 is a total internal reflection (TIR) lens for collimating the light L1.

Total internal reflection (TIR) is an optical phenomenon that occurs when light is incident from a medium with a higher optical density to the surface of a medium with a lower density at an incident angle larger than a particular critical angle with respect to the normal to the surface, and is completely reflected at that boundary without passing through it. This phenomenon is used in the above-mentioned collimating lens.

In an embodiment, the light guide element 42 is an optical fiber.

Continued with mentioned above, an optical fiber, also called fiber-optics, is a high-efficiency light-conducting tool mainly made of glass or plastic. The design of the optical fiber enables it to transmit light in the fiber by using the principle of total internal reflection.

The core of the optical fiber is the fiber core, which is usually made of high-purity glass (quartz glass). The fiber core is wrapped with a layer of glass or plastic with a lower refractive index, which corresponds to the above-mentioned inner cladding layer 421. The two parts form the basic conducting structure of the optical fiber. When light enters the fiber core and is transmitted at a certain angle, total internal reflection occurs at the interface between the fiber core and the cladding layer, thereby transmitting the light in the optical fiber.

In the above embodiment, the inner cladding layer of the optical fiber used in the conventional optical computing device is still transparent, while the outside of the optical fiber of the conventional optical computing device is usually covered with one or more layers of opaque outer layer, such as the aforementioned outer cladding layer 46. The opaque outer layer provides the necessary protection, so that the optical fiber cannot be broken when it is bent or subjected to force. The opaque outer layer may also prevent environmental factors such as moisture and chemicals from damaging the optical fiber, further improving the service life and reliability of the optical fiber.

In an embodiment, the light source 10 is a matrix light source, the light receiver 50 is a matrix light receiver, and each matrix light source corresponds to a single matrix light receiver, which may avoid the interference between the lights L1, further reducing the error of the optical signal.

In an embodiment, the light receiver 50 is a photo detector specially designed for optical computing modules, with high sensitivity, fast response, and wide-band absorption characteristics, capable of effectively converting optical signals into electrical signals, achieving efficient optical computing and data processing. The photo detector is particularly suitable for high-speed optical computing requirements in modern optoelectronic technology.

The photo detector mainly consists of a photoelectric conversion layer, an electrode structure, and a signal processing unit. The photoelectric conversion layer is the core component, in which materials of the photoelectric conversion layer is selected from semiconductor materials with high photoelectric conversion efficiency, such as silicon, gallium arsenide, or organic photoelectric materials. It may rapidly release electron-hole pairs when incident photons arrive, forming a photogenerated current. The design of the photoelectric conversion layer considers the optimization of the spectral response range to cover the commonly used wavelength range of optical computing modules, such as visible light, near-infrared light, and other spectral sections.

The electrode structure is responsible for condensing the photogenerated current generated by the photoelectric conversion layer and transporting it to the signal processing unit. The electrode material is usually selected from transparent conductive materials with excellent electrical conductivity and minimal light absorption, such as indium tin oxide (ITO) or other metal electrodes. The design of the electrode optimizes the incident path of light and the charge transfer efficiency, ensuring that signal loss is minimized.

The signal processing unit is a major technical highlight of the photo detector. It may perform high-precision amplification and data processing on the photogenerated current and generate corresponding digital signals for subsequent logical calculations or information transmission in optical computing modules. This unit integrates efficient analog-to-digital conversion (ADC) circuits and anti-interference designs, ensuring stable performance of the sensor in high-speed optical signal environments.

The packaging design of the photo detector also considers the miniaturization requirements of modern optical computing modules, using high-transparency protective materials and low-power consumption designs to ensure the long-term stable operation of the sensor in harsh environments. Simultaneously, the packaging has high heat dissipation efficiency, suitable for high-frequency computing scenarios.

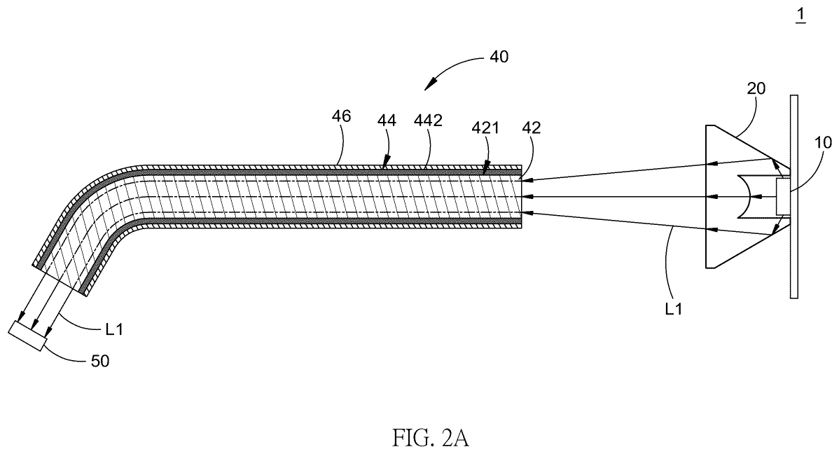

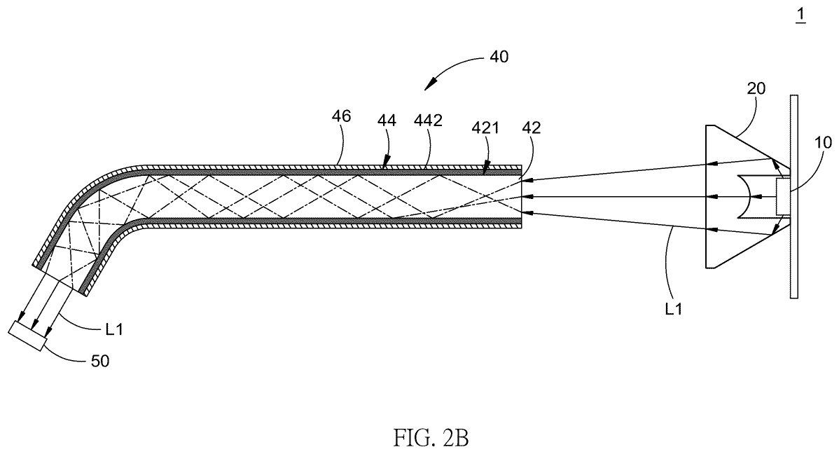

Please refer to FIG. 2A and FIG. 2B, which are the structural schematic diagrams according to the second embodiment of the present application. As shown in the figures, the present embodiment is the second embodiment, which is based on the above-mentioned first embodiment. In the present embodiment, the optical component 40 comprises a channel layer 44, and the inside of the channel layer 44 is filled with a reflective material 442, so that the reflective material 442 covers the outside of the light guide element 42.

Continued with mentioned above, in an embodiment, the reflective material 442 is a material that is opaque and reflects light, such as metal, but the present application is not limited thereto.

Continued with mentioned above, in an embodiment, the refractive index of the reflective material 442 is greater than the refractive index of the light guide element 42, so that the light L1 may be effectively totally reflected on the inner wall of the light guide element 42, thereby improving the overall light guide efficiency of the light guide element 42. The structures and connection relationships of other elements in the present embodiment are the same as the structures and connection relationships in the above-mentioned first embodiment, and thus will not be described herein.

Continued with mentioned above, in an embodiment, the refractive index of the reflective material 442 and the refractive index of the light guide element 42 are greater than the refractive index of the external air.

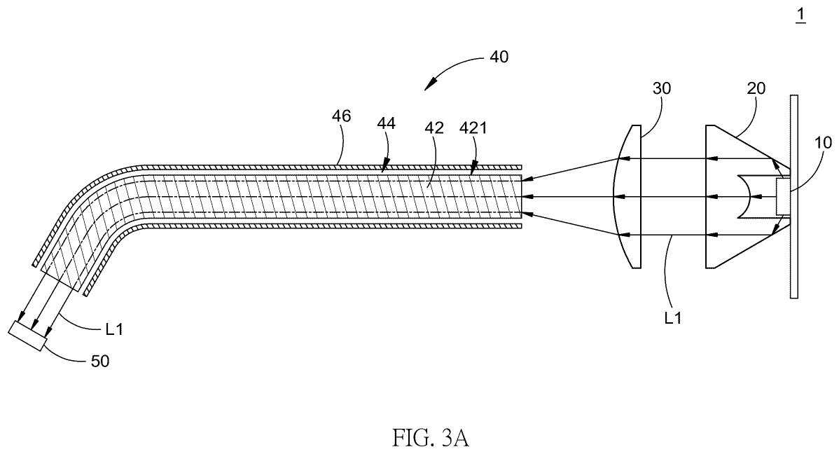

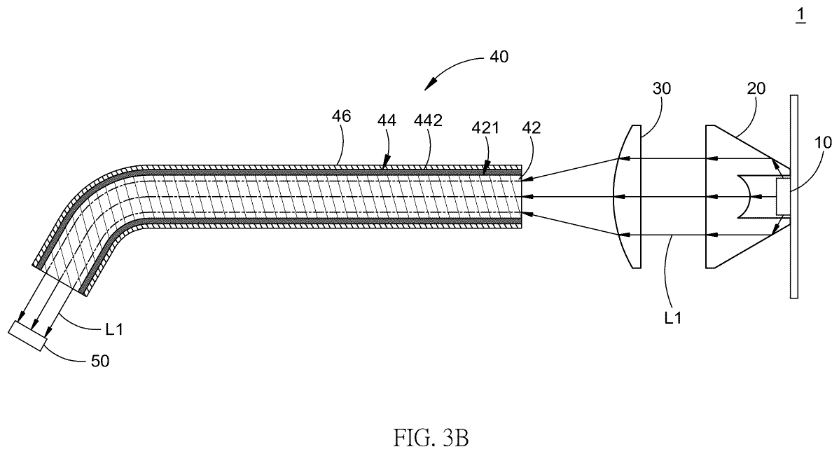

Please refer to FIG. 3A and FIG. 3B, which are the schematic diagrams of the light condensing element according to an embodiment of the present application. As shown in the figures, the present embodiment is based on the above-mentioned embodiments. In the present embodiment, a light condensing element 30 is further comprised. After the lens element 20 receives and collimates the light L1, the light L1 is incident on the object side of the light condensing element 30. The light condensing element 30 is disposed on a side of the lens element 20. The object side of the light condensing element 30 receives the outgoing light L1 and focuses the light L1. The optical component 40 is disposed on a side (image side) of the light condensing element 30.

In an embodiment, the light condensing element 30 is a light condensing lens, which is used to focus the light L1 so that the light L1 may be completely incident on the end of the light guide element 42.

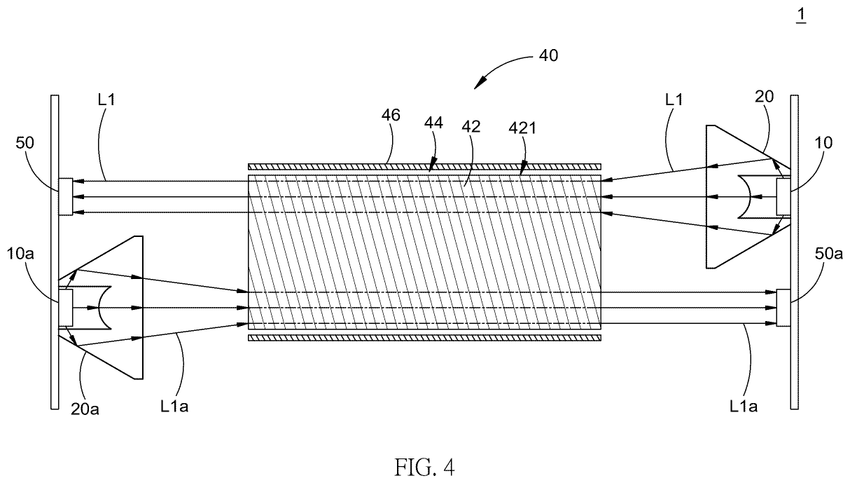

Please refer to FIG. 4, which is a schematic diagram of a mirror image structure according to an embodiment of the present application. As shown in the figure, the present embodiment is based on the above embodiments. In the present embodiment, a light source 10a, a lens element 20a, the optical component 40, and a light receiver 50a are further included. The light source 10a emits a light L1a. The lens element 20a is arranged on the light emitting surface of the light source 10a. The lens element 20a receives and collimates the light L1a. The light receiver 50a is arranged on the light emitting surface of the optical component 40. The light receiver 50a receives the light L1a. The light source 10a, the lens element 20a, and the light receiver 50a are arranged in a mirror image with the light source 10, the lens element 20, and the light receiver 50, respectively. Therefore, the present embodiment may achieve bidirectional optical signal transmission using a single optical component 40.

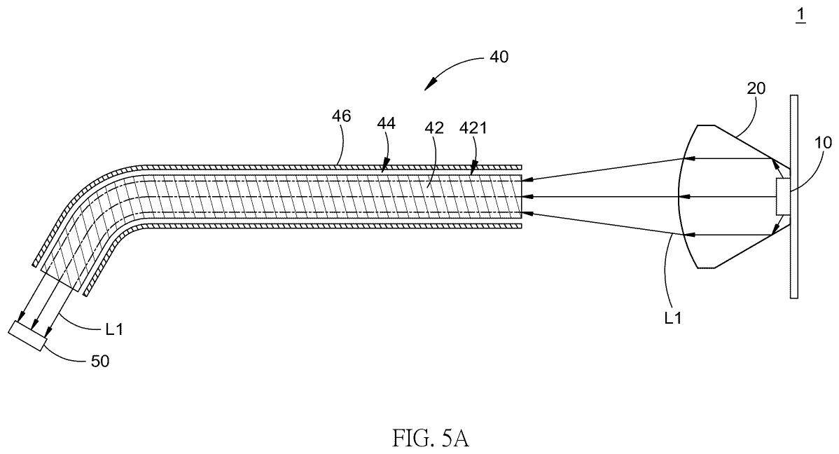

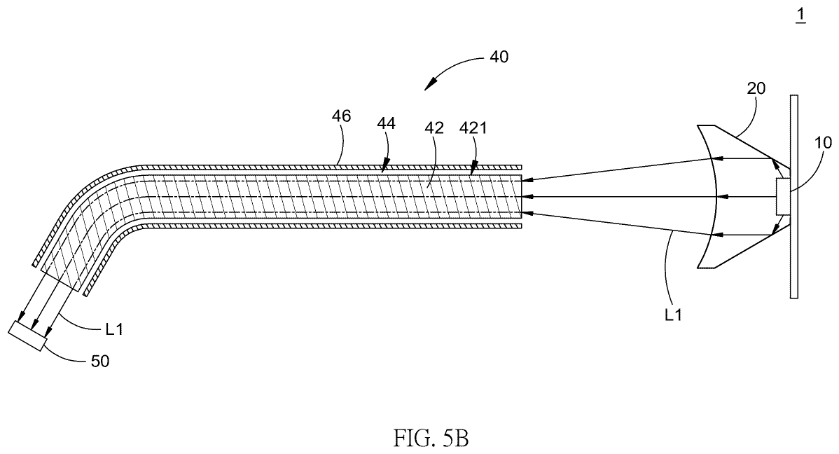

Please refer to FIGS. 5A and 5B, which are schematic diagrams of a lens element according to an embodiment of the present application. As shown in the figures, the present embodiment is based on the above embodiments. In the present embodiment, the light emitting surface of the lens element 20 may be a concave surface or a convex surface. The lens element 20 may adjust the light L1 accordingly to be incident on the light focusing element 30 or the optical component 40. The other elements are the same as the structure and the relationship in the above embodiments, and thus are not described herein again.

To sum up, the present application provides an optical signal transmission device. The transmission efficiency of the optical signal transmission device is improved by using an angle selective film. The light incident angle of the light emitting element is limited, so that the lights with other angles are reflected back to the light emitting element for reuse. The overall light emitting efficiency is improved, so that the lights may be transmitted more evenly and efficiently. The problems of the existing art optical signal transmission device, such as poor light transmittance, light loss in the transmission path, and error in the detection signal or transmission signal, are solved.

What is claimed is

1. An optical computing device, which receives a first signal, converts the first signal into a light, and comprises:
a light emitting element, emitting the light;
a lens element, covering the light emitting element, receiving and collimating the light; and
an optical component, disposed on a side of the lens element, the optical component comprising:
a light guide element, receiving the light on a side and emitting the light from another side of the light guide element;
a channel layer, covering an outer side of the light guide element, a refractive index of the channel layer greater than a refractive index of the light guide element; and
an outer cladding layer, covering an outer side of the channel layer; and
a light receiver, disposed on another side of the light guide element, the light receiver receiving the light and converting the light into a second signal, the second signal being equal to the first signal.

2. The optical computing device of claim 1, wherein the light emitting element is at least one light emitting diode.

3. The optical computing device of claim 1, wherein the lens element is a total reflection collimator lens.

4. The optical computing device of claim 3, further comprising a light condensing element disposed on a side of the lens element and receiving the emitted light.

5. The optical computing device of claim 1, wherein the light guide element is an optical fiber.

6. The optical computing device as claimed in claim 1, wherein the channel layer is filled with a mixed gas or an inert gas.

7. The optical computing device of claim 1, wherein the channel layer is filled with a reflective material.

8. The optical computing device of claim 7, wherein a refractive index of the reflective material is greater than a refractive index of the light guide element.

9. The optical computing device of claim 1, wherein the outer cladding layer is opaque.

10. The optical computing device of claim 1, wherein the light source is a matrix light source and the light receiver is a matrix light receiver.
